(19) United States
(12) Patent Application Publication
(10) Pub. No.: US 2026/0014713 A1
(43) Pub. Date: Jan. 15, 2026

(54) NOZZLE WITH SUPPORT STRUCTURES FOR USE IN A PICK-AND-PLACE MACHINE AND METHODS OF USING THE SAME

(71) Applicant: Taiwan Semiconductor Manufacturing Company Limited, Hsinchu (TW)

(72) Inventors: Jen-Yuan Chang, Hsinchu City (TW); Yi-Xuan Lin, Hsinchu (TW); Chi-Yen Lin, Tainan City (TW)

(21) Appl. No.: 18/769,949

(22) Filed: Jul. 11, 2024

(51) Int. Cl. B25J 15/06; H05K 13/04

(52) U.S. Cl. CPC B25J 15/0683; H05K 13/0409

(57) ABSTRACT

A pick-and-place machine nozzle includes: a planar contact surface configured to form a fluid-tight seal with an electronic component; a nozzle body including a suction chamber; a nozzle tip including a proximal end that is attached to the nozzle body, an opposing distal end that forms a portion of the contact surface, and a nozzle chamber that extends from the opposing distal end to the suction chamber; and a support structure that extends into the nozzle chamber from the opposing distal end, the support structure forming a portion of the contact surface.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

In addition to smaller electronic components, improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (POP), System on Chip (SoC) or System on Integrated Circuit (SoIC) devices. Some of these 3D devices (e.g., 3DIC, SoC, SoIC) are prepared by placing chips over chips on a semiconductor wafer level.

Semiconductor devices may be assembled using pick-and-place machines (e.g., pick-and-place machines) that include complex robots that have dispensing heads that move along one or more axis to assemble an unfinished product. Dispensing heads may be capable of picking and/or placing a component from one surface to another surface. In pick-and-place machines, for example, dispensing heads are often configured to receive multiple different spindle and nozzle assemblies in order to pick, place, and assemble various different parts efficiently. Dispensing heads often include a spindle assembly for creating rotation in a nozzle, along with the ability to move the nozzle in the Z-axis.

Further, pick-and-place machines may include multi-spindle or multi-nozzle dispensing heads. These dispensing heads may be configured to, for example, pick up multiple components from one or more feeder banks, and then move to a placement location to place the multiple components. These pick-and-place machines that include multi-spindle or multi-nozzle dispensing heads reduce assembly time as compared to pick-and-place machines that include a single spindle or single nozzle. This is because single spindle and nozzle arrangements will typically require the multiple back and forth movements between the feeder banks and the placement location with each placed component.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a pick-and-place machine, according to various embodiments of the present disclosure.

FIG. 2A is a perspective view showing the pick-and-place machine of FIG. 1 with covers removed.

FIG. 2B is a perspective view showing an enlarged portion A of FIG. 2A.

FIG. 3 is a perspective view of a spindle module, according to various embodiments of the present disclosure.

FIG. 4A is a flow diagram depicting a method of picking and placing of electronic components, according to various embodiments of the present disclosure.

FIGS. 4B and 4C are schematic views showing the operation of a pick-and-place head during the method of FIG. 4A, according to various embodiments of the present disclosure.

FIG. 5A is a plan view of a nozzle.

FIG. 5B is a cross-sectional view of the nozzle and an attached to a semiconductor die.

FIG. 5C is a transparent perspective view illustrating the warpage of a semiconductor die attached to a nozzle tip.

FIG. 5D is a photograph showing warpage of a semiconductor die attached to a nozzle.

FIG. 6A is a plan view of a nozzle, according to various embodiments of the present disclosure.

FIG. 6B is a cross-sectional view taken along line L1 of FIG. 6A.

FIG. 6C is a cross-sectional view showing the nozzle of FIG. 6A attached to a semiconductor die.

FIG. 6D is a plan view showing a contact surface disposed on a semiconductor die.

FIG. 7A is a plan view of a nozzle including an alternative support structure, according to various embodiments of the present disclosure.

FIG. 7B is a cross-sectional view taken along line L2 of FIG. 7A.

FIG. 8A is a plan view of a nozzle including an alternative support structure, according to various embodiments of the present disclosure.

FIG. 8B is a cross-sectional view taken along line L3 of FIG. 8A.

FIG. 9A is a plan view of a nozzle including an alternative support structure, according to various embodiments of the present disclosure.

FIG. 9B is a cross-sectional view taken along line L4 of FIG. 9A.

FIGS. 10A-10J are plan views showing contact surfaces formed by alternative support structures, according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Pick-and-place machines play an influential role in automating the placement of electronic components from one location to another. For example, pick-and-place machines may be used to pick up electric components, such as semiconductor dies, resistors, capacitors, etc., from reels, wafers, trays, or frames, and to place the electric components onto a printed circuit board (PCB). For example, pick-and-place machines may be fitted with various types of nozzles designed to pick up different electric components. Automation with pick-and-place machines enhances production throughput, allowing for the rapid assembly of PCBs in large quantities.

Semiconductor dies are currently being manufactured to have smaller and smaller dimensions. For example, advanced SoIC dies may have smaller thickness and may be more susceptible to warpage and damage due to rough handling by a pick-and-place machine. In particular, the nozzles used in related pick-and-place machines may warp and/or damage relatively fragile advanced semiconductor dies in instances where the pick-and-place machines use a suction to pick up and move the semiconductor dies. The application of suction (e.g., negative vacuum pressure) to the related nozzle may result in the deformation of a semiconductor die attached thereto. The warpage of the semiconductor die may produce internal stress upon the semiconductor die, which may result in internal damage to the semiconductor die. In addition, results in warpage of the semiconductor die may result from the nozzle tip rubbing against the semiconductor die. This may scratch and/or damage (e.g., chip) the semiconductor die. Accordingly, semiconductor die warpage may reduce product yield and reliability of the of the pick-and-place process. The various embodiments disclosed herein provide a reinforced support structure that may be configured to reduce and/or prevent die warpage.

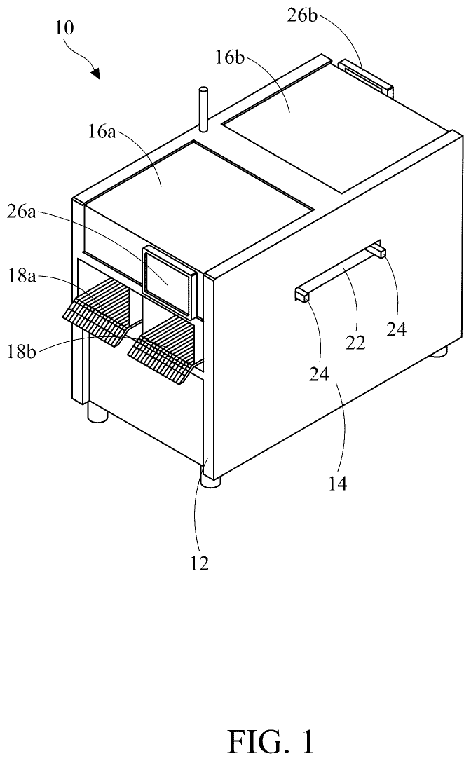

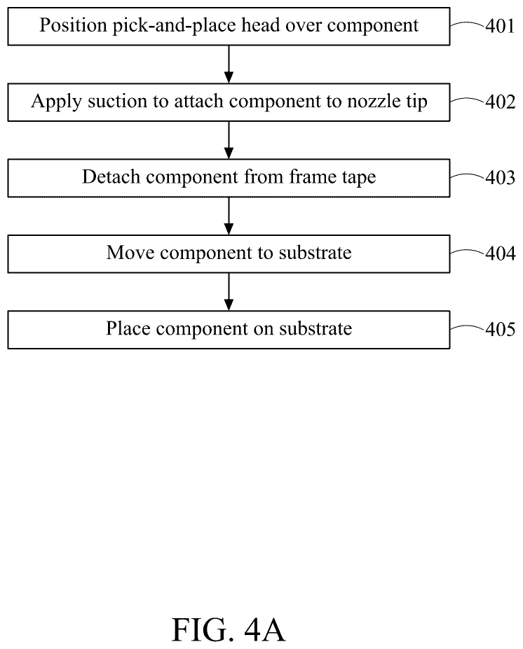

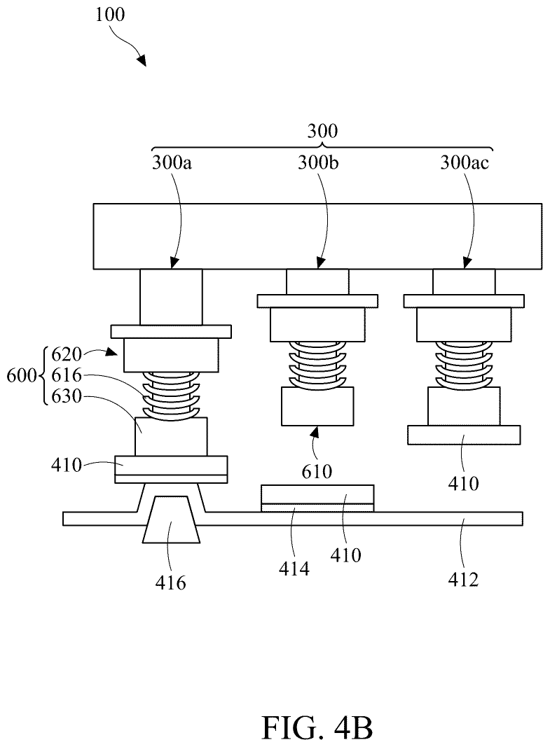

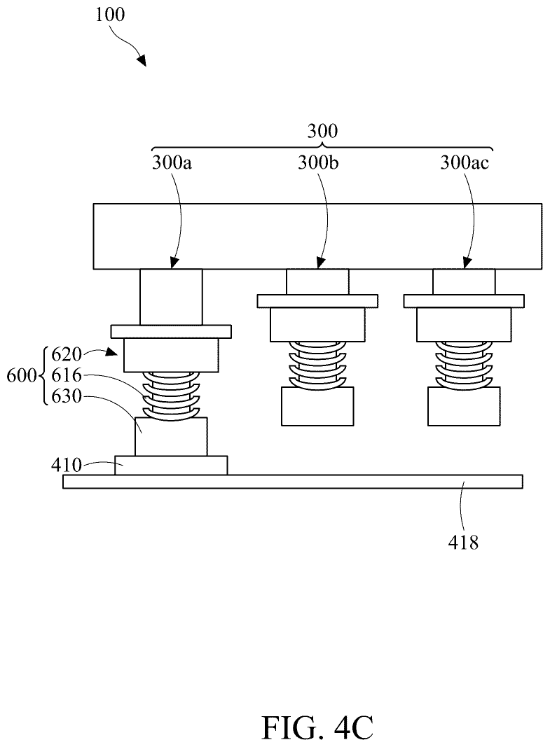

FIG. 1 is a perspective view of a pick-and-place machine 10. Referring to FIG. 1, the pick-and-place machine 10 may be configured to assemble a printed circuit board (PCB) in the embodiment shown. For example, the pick-and-place machine 10 may be an advanced packaging pick-and-place machine, a component pick-and-place machine, or the like. In other embodiments, the elements described herein may be applied to various other pick-and-place machines such as odd form pick-and-place machines (OFA), or the like. The pick-and-place machine 10 includes a frame 12 providing structure a body 14 having covers 16a, 16b. The frame 12 may include a plurality of legs upon which the pick-and-place machine 10 is configured to stand. The pick-and-place machine 10 may include a plurality of feeder banks 18a, 18b. Frame tapes (shown in FIG. 4A) may be mounted to each of the feeder banks 18a, 18b. The frame tapes may each include electronic components that the pick-and-place machine 10 is configured to pick up and place onto a PCB, to assemble or at least partially assemble the PCB.

The pick-and-place machine 10 may further include a board handling opening 22. A board handling track 24 may extend within the body 14 of the pick-and-place machine 10 extending between the opening 22 and another opening on the opposing side of the pick-and-place machine (not shown). The board handling track 24 may be configured to receive a PCB or another unfinished product and transport the PCB to a placement location within the body of the pick-and-place machine 10 for assembly. The pick-and-place machine 10 illustrated in FIG. 1 may include an operator interface and control displays 26a, 26b, one on each side. The display 26 (i.e., 26a, 26b) may be configured to receive user or operator inputs and display information necessary or useful to a user or operator. While the features of the pick-and-place machine 10 shown are one exemplary embodiment, aspects of the invention described herein are applicable to various other types of pick-and-place machines as will be apparent to those skilled in the art.

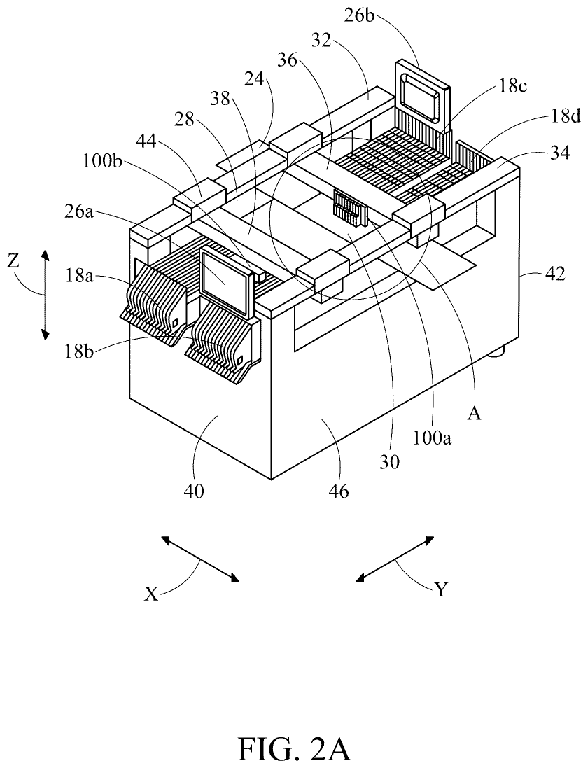

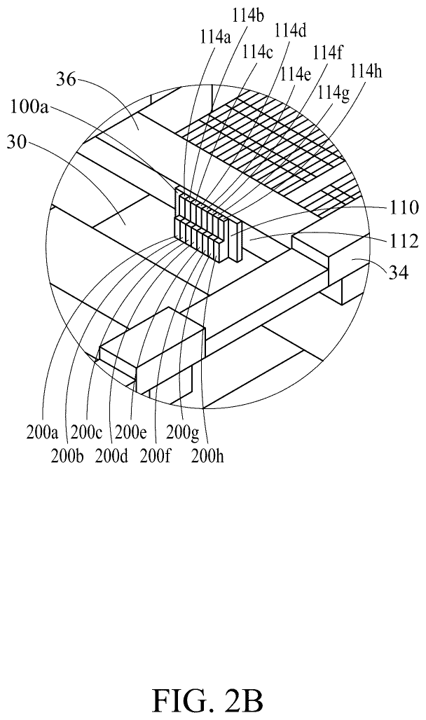

Referring now to FIG. 2A, the pick-and-place machine 10 is shown with the covers 16a, 16b removed. Thus, the pick-and-place machine 10 shown in FIG. 2A illustrates an exposed interior 28 of the pick-and-place machine 10. The pick-and-place machine 10 may include two additional feeder banks 18c, 18d disposed on the opposite side of the body 14 as the feeder banks 18a, 18b. The board handling track 24 may be located between the feeder banks 18a, 18b and 18c, 18d. The board handling track 24 may be configured to provide an unfinished product such as a PCB to a placement station 30 located along the track 24.

The pick-and-place machine 10 may facilitate movement of components in three movement axes: an x-axis, a y-axis, and a z-axis. Hereinafter, the x-axis may be an axis extending parallel to the board handling track 24. The y-axis may be perpendicular to the x-axis and the board handling track 24. The z-axis may be an up and down or vertical axis. The pick-and-place machine 10 may include a plurality of movement axes 32, 34, 36, 38 for facilitating movement in the x-axis and the y-axis. In particular, the pick-and-place machine 10 may include a first movement axis 32 and a second movement axis 34 that are configured to facilitate movement in the y-axis. The pick-and-place machine 10 may include a third movement axis 36 and a fourth movement axis 38 that are each configured to facilitate movement in the x-axis. The first movement axis 32 and the second movement axis 34 may extend along a depth of the machine between a first side 40 and a second side 42. The first side 40 is the side of the pick-and-place machine 10 proximate the first feeder bank 18a and the second feeder bank 18b. The second side 42 is the side of the pick-and-place machine 10 proximate the third feeder bank 18c and the fourth feeder bank 18d. The third movement axis 36 and the fourth movement axis 38 are both shown connected to the first movement axis 32 and the second movement axis 34 and extend there between.

During operation of the pick-and-place machine 10, the third movement axis 36 and the fourth movement axis 38 are configured to each independently move along the first movement axis 32 and the second movement axis 34 to provide for movement in the y-axis. Pick-and-place heads 100a, 100b are movably attached to each of the third movement axis 36 and the fourth movement axis 38, respectively. The pick-and-place heads 100a, 100b may each be configured to move along the x-axis by moving along the respective third movement axis 36 and fourth movement axis 38. In other embodiments, the pick-and-place machine 10 may be a single-moveable axis machine. For example, there may be a single x-axis and a single y-axis connectable to the pick-and-place machine.

With the first movement axis 32, second movement axis 34, third movement axis 36, and fourth movement axis 38, the pick-and-place heads 100a, 100b within the pick-and-place machine 10 may be configured for both x-axis and y-axis freedom of operation within the interior 28. This allows the pick-and-place heads 100a, 100b to move back and forth to and from the feeder banks 18a, 18b, 18c, 18d and the placement station 30. This is accomplished by both the movement of the pick-and-place heads 100a, 100b along the respective third movement axis 36, and fourth movement axis 38, and the movement of the third movement axis 36, and fourth movement axis 38 along the first movement axis 32 and second movement axis 34. Other forms of x-axis and y-axis movement within the pick-and-place machine 10 are contemplated and the movement axes shown are for exemplary purposes.

Referring now to FIG. 2B, a perspective view of a portion of the pick-and-place machine 10 enlarged at circle A (from FIG. 2A) is shown. The enlarged portion shows the pick-and-place head 100a having a base 110 and a bearing system 112. The base 110 may be a body, housing, structure or the like. The base 110 may include a plurality of mount locations 114a, 114b, 114c, 114d, 114e, 114f, 114g, 114h each configured to receive a spindle module 200a, 200b, 200c, 200d, 200e, 200f, 200g, 200h, respectively (collectively referred to as spindle module 200). The spindle modules described herein may be pick-and-place spindle modules particularly configured for receiving spindle and nozzle combinations that are configured to pick, place, or otherwise manipulate electronic components for printed circuit board assembly and picking and placement processes. The spindle modules described herein may also be utilized for other assembly processes where one or more rotatable and/or descendible manipulating spindles are necessary to perform at least a portion of an assembly process for assembling an unfinished product.

The bearing system 112 may be a system that provides for movement of the pick-and-place head 100a along the third movement axis 36. The bearing system 112 may include wheels to facilitate movement between the pick-and-place head 100a and the movement axis 36. In other embodiments, the bearing system 112 may include magnets to facilitate magnetic movement between the pick-and-place head 100a and the third movement axis 36. The third movement axis 36 may include a track structure on the underside (not shown) that may cooperate with a track structure bearing system of the pick-and-place head 100a. For example, the pick-and-place head 100 may include track runner bearings configured to cooperate with a track of the third movement axis 36. A motor or other movement creating mechanism may provide for controlled powered movement of the pick-and-place head 100 along the third movement axis 36. The motor may be located on the pick-and-place head itself 100 or may be located on the third movement axis 36. Thus, the pick-and-place head 100 may include one or more electrical ports, connectors or the like to connect to an electrical system of the pick-and-place machine 10 to thereby provide electrical power to the pick-and-place head 100. The pick-and-place head 100 may utilize this electricity to power a motor or otherwise provide motion, movement, or acceleration of the pick-and-place head 100 relative to the third movement axis 36.

The mount locations 114a, 114b, 114c, 114d, 114e, 114f, 114g, 114h may provide for modularity in the pick-and-place head 100a such that the pick-and-place head 100a may be operable with each of the spindle modules 200a, 200b, 200c, 200d, 200e, 200f, 200g, 200h attached or with a single one of the spindle modules. In other words, the pick-and-place head 100a may be operable regardless of how many of the spindle modules 200a, 200b, 200c, 200d, 200e, 200f, 200g, 200h are installed into the mount locations 114a, 114b, 114c, 114d, 114e, 114f, 114g, 114h. In other embodiments, the pick-and-place head 100a may include mount locations that have different physical attachment properties to provide for attachment of modules having different attachment mechanisms or properties than other modules attachable in other mount locations on the pick-and-place head 100a.

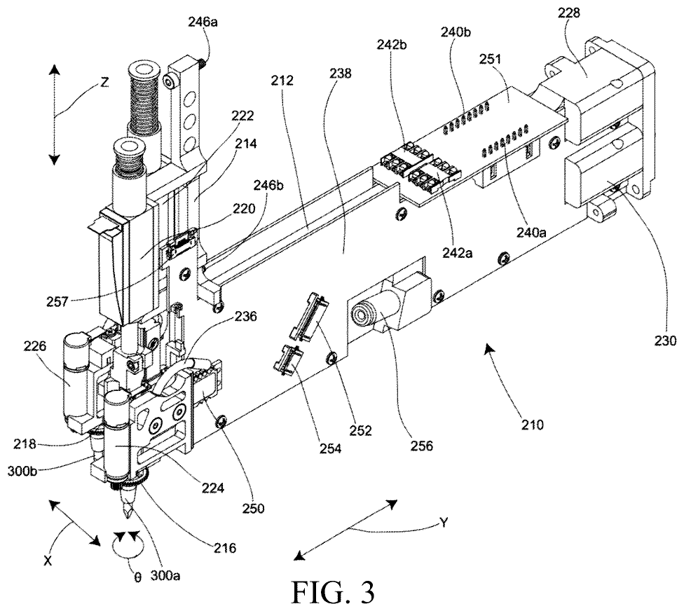

Referring now to FIG. 3, an enlarged view of a spindle module 200 is shown. The spindle module may be the same as one of the spindle modules 200a, 200b, 200c, 200d, 200e, 200f, 200g, 200h shown in FIG. 2B. The spindle module 200 is shown including a modular body structure 210. The modular body structure may include a first body structure 212 and a second body structure 214 mounted or attached to the first body structure 212. The second body structure 214 may include a first receiving location 216 configured to receive a first spindle 300a, and a second receiving location 218 configured to receive a second spindle 300b.

The spindle module 200 further includes a first z-axis motor 220 and a second z-axis motor 222, each mounted to the second body structure 214. The first z-axis motor 220 may be configured to move the first spindle 300a in the z-axis direction. Similarly, the second z-axis motor 222 may be configured to move the second spindle 300b in the z-axis direction. The spindle module 200 further includes a first theta motor 224 and a second theta motor 226. The first theta motor 224 may be configured to rotate the first spindle 300a in a theta (0) rotational axis. The second theta motor 226 may be configured to rotate the second spindle 300b in the theta (0) rotational axis. The first theta motor 224 and the second theta motor 226 may be configured to provide theta axis rotation in either directions. Thus, the spindle module 200 may provide for movement in the z-axis as well as rotational movement in the theta (0) rotational axis. The spindle module 200 may provide for independent movement for each of the first spindle 300a and second spindle 300b.

The spindle module 200 may further include an air distribution system that includes one or more valves 228, 230, along with two airflow tubes 236 (one shown), each providing vacuum generating airflow to the first spindle 300a and second spindle 300b. The air distribution system may further include a pneumatic connector 256 (one shown) on each side. Internal airflow tubes (not shown) may provide this airflow to the pneumatic connectors 256. The airflow tubes 236 may connect to the pneumatic connectors 256 by elongating the airflow tubes or using another tube that connects the pneumatic connectors 256 to the airflow tubes 236, respectively. In the embodiment shown, the first valve 228 is housed within a widened portion of the first body structure 214 and may provide for air-kiss forward air pressure. The second valve 230 is also shown to be housed within a widened portion of the first body structure 214 and may be a valve for providing vacuum pressure for picking up a component with the first spindle 300a and the second spindle 300b.

The spindle module 200 may have outer bodies 238 mounted to the first body structure 212 with several screws or other fastener. The outer bodies 238 may be circuit boards. As shown, the spindle module 200 may include an electrical distribution system including a second circuit board assembly 251 containing a plurality of electrical distribution ports 242a, 242b configured to receive electrical current from the pick-and-place machine 10 and/or the pick-and-place head 100a or 100b in instances in which the pick-and-place head 100a or 100b is attached and delivers the received electrical current to the first z-axis motors 220 and second z-axis motor 222 as well as the first theta motor 224 and the second theta motor 226. In embodiments in which the spindle module 200 is attached to the pick-and-place machine 10, each of the electrical distribution ports 242a and 242b may be attached to electrical connectors of the pick-and-place machine 10 or pick-and-place heads 100a or 100b.

In one embodiment, the ports 240a, 240b may be configured to deliver electricity from the distribution ports 242a and 242b to the outer bodies 238 and to electrical connectors 252, 254, 257. It should be understood that the electrical connectors 252, 254 and 257 may be located on one side of the spindle module 200, the other side of the spindle module 200, and/or on both sides of the spindle module 200. Thus, electricity may travel through the distribution port 242a, port 240a, outer body 238, electrical connector 257, and a cable (not shown) to the first z-axis motor 220. Similarly, electrical current may conduct through the distribution port 242a, through port 240a, electrical connector 252, and ta cable (not shown) to the first theta motor 224. Connector 254 may be used to connect to a spindle module optical detector (not shown) to the motion control chip 250.

The spindle modules 200 may include one or more mechanical attachment mechanisms to facilitate attachment of the spindle modules 200 to the pick-and-place machine 10, and thereby form one of the pick-and-place heads 100a, 100b. In the embodiment shown, the mechanical attachment mechanisms comprise a first threaded screw 246a and a second threaded screw 246b. Other fastening devices may be contemplated.

The spindle module 200 may further include a first motion control chip 250 attached to the first body structure 212 proximate the second body structure 214 and the first z-axis motor 220, second z-axis motor 222, the first theta motor 224 and the second theta motor 226. An opposite side of the first body structure 212 may include a second motion control chip (not shown) in a mirrored location as the first motion control chip 250. The first motion control chip 250 may be configured to control the first z-axis motor 220 and the first theta motor 224. The motion control chip 250 may thus be a dedicated control chip, processor, or the like, configured to control only one of the two spindles 300a, 300b contained in the spindle module 200, in particular the first spindle 300a. The second motion control chip may be a dedicated control chip, processor, or the like configured to control the second spindle 300b. Each of the first motion control chip 250 and the second motion control chip (not shown) may be configured to control speed, acceleration, and position of the respective first z-axis motor 220 and the second z-axis motor 222 as well as the first theta motor 224 and second theta motor 226.

FIG. 4A is a flow diagram depicting a method of picking and placing of electronic components, according to various embodiments of the present disclosure. FIGS. 4B and 4C are schematic views showing the operation of a pick-and-place head 100 during the method, according to various embodiments of the present disclosure. Referring to FIGS. 4A and 4B, the pick-and-place head 100 may include at least one spindle 300, such as spindles 300a, 300b, 300c, etc. However, in other embodiments, the pick-and-place head 100 may include a single spindle 300 or additional spindles 300. A nozzle 600 may be attached to each of the spindles 300. Each nozzle 600 may comprise a nozzle body 620, a nozzle tip 630, and an optional spring 616. The nozzles 600 may have a contact surface 610 configured to establish a fluid tight connection with an electronic component, such as a semiconductor die 410.

In operation 401 of the method, the pick-and-place head 100 may be positioned over a component carrier, such as a frame tape 412. The frame tape 412 may be provided by a feeder bank 18 (e.g., feed bank 18a, 18b) as shown in FIG. 1. Multiple electronic components, such as semiconductor dies 410, may be attached to an upper surface of the frame tape 412, for example, by an adhesive layer 414.

The pick-and-place head 100 may be operated to position a spindle 300 over a selected one of the semiconductor dies 410. For example, the spindle 300a may be moved along the x-axis, y-axis, and/or z-axis such that the spindle 300a vertically overlaps with the semiconductor die 410. The semiconductor die 410 may be positioned over a thimble 416. The thimble 416 may be moved upward in a vertical direction, such that the semiconductor dies 410 is also moved upward toward the spindle 300 in the vertical direction and is disposed above adjacent semiconductor dies 410 attached to the frame tape 412.

In some embodiments, the spindle 300a may also be extended downward in the vertical direction towards the semiconductor die 410, in order to move the nozzle 600 into contact with a semiconductor die 410. As a result, of the motion of the thimble 416 and/or the spindle 300a, the nozzle tip 630 contacts a top surface of the semiconductor die 410.

In operation 402 of the method, suction may be applied to the spindle 300a by the pick-and-place head 100 in order to attach the semiconductor die 410 to the nozzle 600. For example, a partial vacuum may be formed within the nozzle 600 and applied to the top surface of the semiconductor die 410. In other words, the semiconductor die 410 may be secured to the nozzle 600 by suction (vacuum force). The nozzle tip 630 may be formed of a compliant material, such as rubber or a flexible polymer. As such, the nozzle tip 630 may be configured to form a gas tight seal on the upper surface of the semiconductor die 410.

In operation 403 of the method, the semiconductor die 410 may then be detached from the frame tape 412. For example, the pick-and-place head 100 may be moved upward away from the frame tape 412 and/or the spindle 300a may be retracted into the pick-and-place head 100. For example, the spindles 300b, 300c are shown in a retracted position, while spindle 300a is shown in an extended position.

In other embodiments, the semiconductor die 410 may be picked from a substrate other than the frame tape 412. For example, the semiconductor die 410 may be picked from a semiconductor wafer, a chip frame, or a box or container.

Referring to FIGS. 4A and 4C, in operation 404 of the method, the semiconductor die 410 may be moved to a new location. For example, the pick-and-place head 100 may be moved in the X, Y, and/or Z directions to place the semiconductor die 410 on a substrate 418. In various embodiments, the substrate 418 may be a PCB, a semiconductor die, a semiconductor wafer, a box or container, or a chip frame.

After positioning the semiconductor die 410 over a desired location, in a fifth operation 405 of the method the semiconductor die 410 may be released from the nozzle tip and placed on the substrate 418. In particular, the suction (i.e., vacuum) in the spindle 300a may be released to release the semiconductor die 410 from the nozzle tip 630. The method may also include repeating the operations 401-405 one or more times to pick-and-place additional components.

### Semiconductor Die Protection

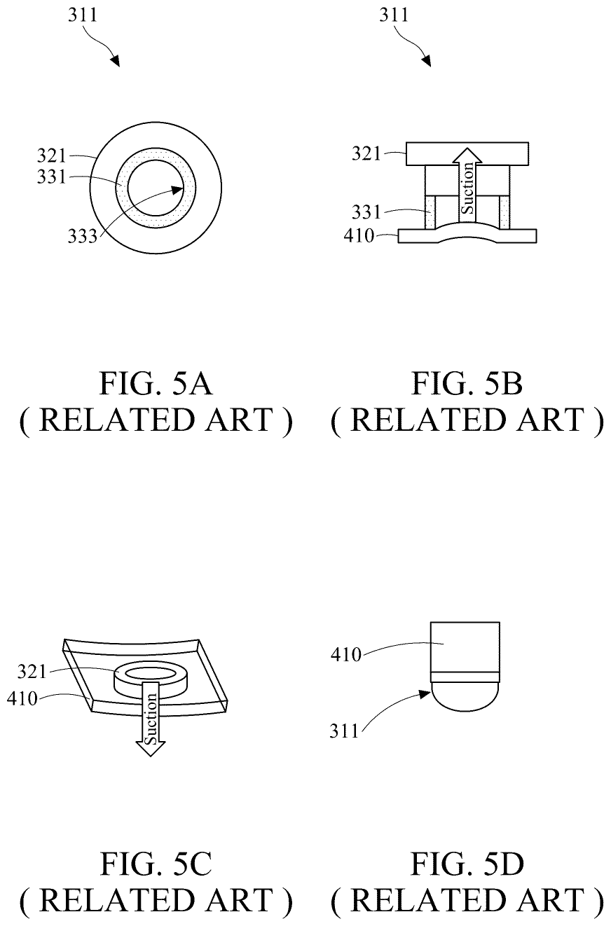

Semiconductor dies are currently being manufactured to have smaller and smaller dimensions. For example, advanced SoIC dies may have a thickness of about 100 μm, while a C4 bump die may have a thickness of about 800 μm. As such, modern semiconductor dies may be less robust, which complicates the handling thereof. In particular, as discussed in detail below with respect to FIGS. 5A-5D related nozzles may warp and/or damage relatively fragile advanced semiconductor dies.

FIG. 5A is a plan view of a related pick-and-place nozzle 311, FIG. 5B is a cross-sectional view of the related nozzle 311 showing an attached to a semiconductor die 410, FIG. 5C is a transparent perspective view illustrating the warpage of a semiconductor die 410 attached to a related nozzle tip 331, and FIG. 5D is a photograph showing warpage of a semiconductor die 410 attached to the related nozzle 311.

Referring to FIG. 5A, the nozzle 311 includes a nozzle tip 331 attached to a nozzle body 321. The nozzle tip 331 may be generally cylindrical or conical in shape. Other nozzle tip shapes are within the contemplated scope of disclosure. The nozzle tip 331 may have a circular nozzle opening 333.

As shown in FIGS. 5B-5D, the application of suction (e.g., negative vacuum pressure) to the nozzle 311, as shown by the suction arrow, results in deformation of a semiconductor die 410 attached thereto. The warpage of the semiconductor die 410 may produce internal stress upon the semiconductor die 410, which may result in internal damage to the semiconductor die 410. In addition, results in warpage of the semiconductor die 410 may result in the nozzle tip 331 rubbing against the semiconductor die 410. This may scratch and/or damage (e.g., chip) the semiconductor die 410. Accordingly, semiconductor die warpage may reduce product yield and reliability of the of the pick-and-place process. As such, the present disclosure provides improved nozzle tips that are configured to reduce and/or prevent die warpage.

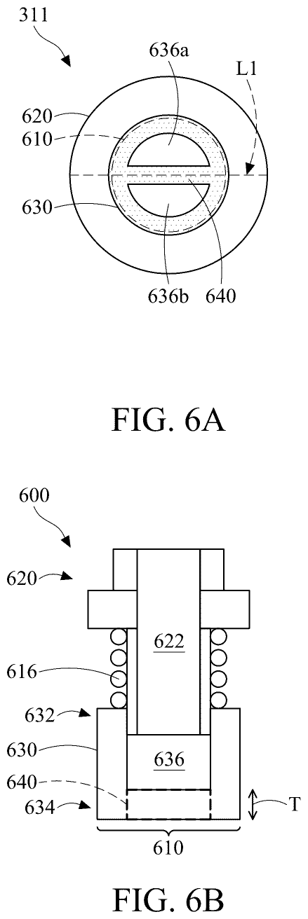

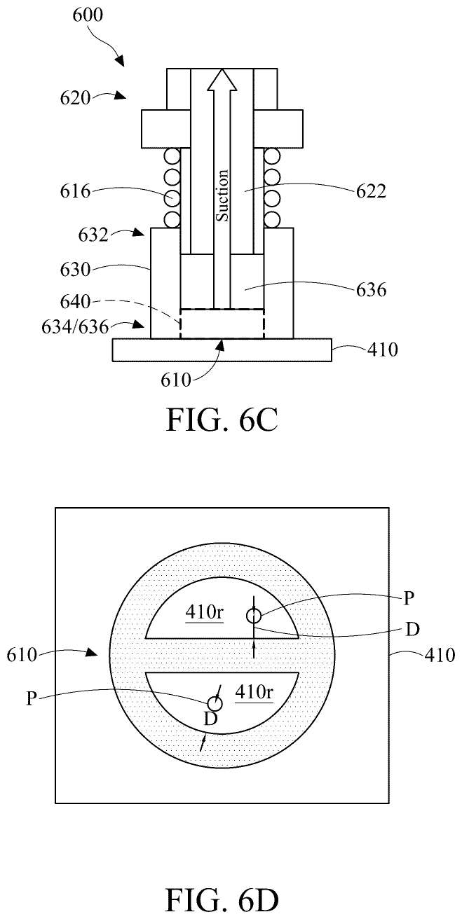

FIG. 6A is a plan view of a pick-and-place nozzle 600, according to various embodiments of the present disclosure. FIG. 6B is a cross-sectional view taken along line L1 in FIG. 6A. FIG. 6C is a cross-sectional view illustrating the nozzle 600 in an operating position and attached to a semiconductor die 410. FIG. 6D is a plan view showing a contact surface disposed on a semiconductor die 410.

Referring to FIGS. 4A, 6A, and 6B, the nozzle 600 may be coupled to a spindle 300 of a pick-and-place head 100. The nozzle 600 may include a contact surface 610, a nozzle body 620, a nozzle tip 630, and an optional spring 616 biased between the nozzle tip 630 and a portion of the nozzle body 620. The nozzle body 620 may include a suction chamber 622. The nozzle body 620 may be configured to be removably attached to a spindle 300. The nozzle body 620 may be formed of any suitable material, such as metal or plastic. Other suitable materials for the nozzle body 620 are within the contemplated scope of disclosure.

The nozzle tip 630 may have a generally cylindrical shape. However, the nozzle tip 630 is not limited to any particular shape and may be for example, conical, prismatic, or the like. Other suitable shapes for the nozzle tip 630 are within the contemplated scope of disclosure. The nozzle tip 630 may be formed of a flexible rubber or plastic material and may be connected to the nozzle body 620. Other suitable materials for the nozzle tip 630 are within the contemplated scope of disclosure.

The nozzle tip 630 may include a nozzle tip chamber 636 that is fluidly connected to the suction chamber 622. The nozzle tip 630 may include a proximal end 632 that is attached to the nozzle body 620 and an opposing distal end 634. The opposing distal end 634 may have an external planar surface that faces away from the nozzle body 620.

A support structure 640 may be disposed within the nozzle chamber 636 at the opposing distal end 634 of the nozzle tip 630. The support structure 640 may have an external planar surface that faces away from the nozzle body 620. The support structure 640 may have a prismatic shape, such as a rectangular prism or a triangular prism. However, other shapes are within the scope of the present disclosure. The support structure 640 may extend into nozzle chamber 636 to form into separate nozzle chamber openings 636a, 636b.

The external surfaces of the support structure 640 and the opposing distal end 634 may be coplanar and may form the contact surface 610 of the nozzle 600. In particular, the distal end 634 may form a perimeter portion of the contact surface 610 and the support structure 640 may form an internal portion of the contact surface. In other words, the support structure 640 may be disposed inside of the opposing distal end 634.

The contact surface 610 may be configured to establish a fluid tight vacuum connection with an electronic component such as a semiconductor die 410. In particular, the support structure 640 may be configured to support the electronic component within a suction (i.e., negative pressure vacuum) region defined by the perimeter of the nozzle chamber 636, in order to limit an amount of stress applied to the electronic component by the applied suction. For example, the support structure 640 may be configured to reduce an amount of bending stress that is applied to an electronic component that is attached to the nozzle tip 630 by a partial vacuum generated in the suction chamber 622 and the nozzle chamber 636.

As shown in FIG. 6C, when a negative pressure is generated in the suction chamber 622, suction connects the semiconductor die 410 to the nozzle 600. In particular, the suction is applied to a portion of the upper surface of the semiconductor die 410 through the nozzle chamber 636 of the distal end 634, such that the semiconductor die 410 is pressed against the contact surface 610. Since the support structure 640 supports the semiconductor die 410, the stress applied to the semiconductor die 410 is reduced, as compared to a related nozzle tip 331 that lacks a support structure, such as support structure 640. Accordingly, the support structure 640 used in the various embodiments disclosed herein may be configured to reduce and or prevent electronic component warpage and/or damage.

As shown in FIG. 6B, the support structure 640 may have a thickness T sufficient to minimize or prevent warping of the electronic component (e.g., semiconductor die 410). For example, the thickness T may range from about 1 mm to about 10 mm, such as from about 2 mm to about 5 mm. However, other thicknesses are possible, depending on the strength of the material used to form the support structure 640. In various embodiments, the support structure 640 and the nozzle tip 630 may be formed of the same material, such as a flexible rubber material. In other embodiments, the support structure 640 and the nozzle tip 630 may be formed of different materials.

Referring to FIGS. 6C and 6D, in some embodiments, the contact surface 610 may have a radius that is based on the size of a component to be picked up by the nozzle tip 630. For example, the radius may range from about 0.5 mm to about 300 mm, such as from about 10 mm to about 200 mm, or from about 50 mm to about 100 mm. support structure 640 may be configured such that a distance D between any point P on a vacuum exposed surface region 410r of the electronic component (e.g., semiconductor die 410) and the nearest portion of the contact surface 610 is no more than a set distance, in order to support the semiconductor die 410 and limit warpage of the semiconductor die 410. For example, the distance D may range from about 0 mm to about 0.9 times the radius (i.e., 0.9*radius). In some embodiments, the distance D may range 0.01*radius to about 0.5*radius, such as from about 0.1*radius to about 0.4*radius, or from about 0.2*radius to about 0.3*radius.

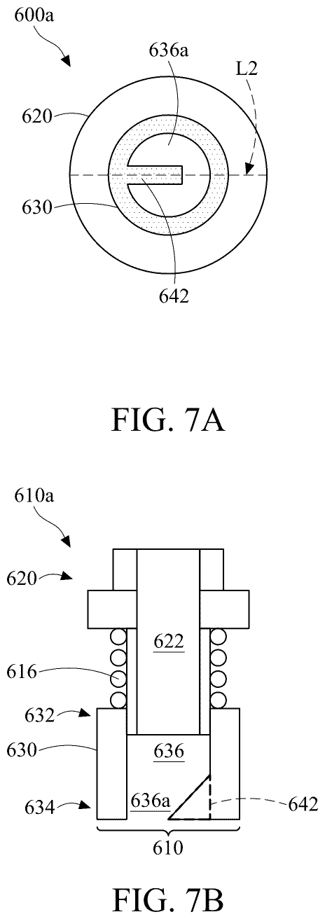

FIG. 7A is a plan view of a nozzle 600a including an alternative support structure 642, according to various embodiments of the present disclosure. FIG. 7B is a cross-sectional view taken along line L2 of FIG. 7A. The nozzle 600a may be similar to the nozzle 600 of FIGS. 6A-6C. As such, only the differences there between will be discussed in detail.

Referring to FIGS. 7A and 7B, the support structure 642 may be disposed in the opposing distal end 634 of the nozzle tip 630. The support structure 642 may be connected to only one side of the nozzle tip 630. The support structure 642 may have a linear horizontal cross-section. The support structure 642 may have a triangular vertical cross-section, in order to provide additional strength to the support structure 642. However, in other embodiments, the support structure 642 may have a rectangular vertical cross-section. Still further in other embodiments, the support structure may have a semi-circular vertical cross section or quarter circular vertical cross section. The support structure 642 may extend into the nozzle chamber 636 from one side of the opposing distal end 634 to form a partially divided nozzle chamber opening 636a. In some embodiments, the length of the support structure 642 may be at least about half of the inner diameter of the distal end 634, although shorter or longer lengths may be used. In other words, the support structure 642 may extend across more than half of the nozzle chamber opening 636a. In some embodiments, the support structure 642 may extend across half or less than half of the width of the nozzle chamber opening 636a. For example, the length of the support structure 642 may range from about 45% to about 75% of the diameter of the nozzle tip 630.

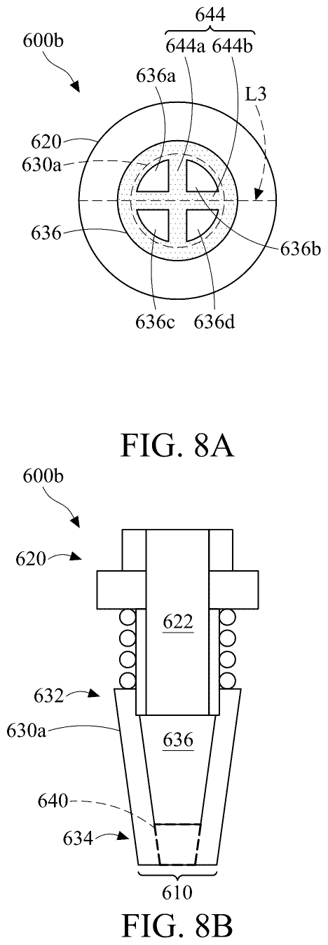

FIG. 8A is a plan view of a nozzle 600b including an alternative support structure 644, according to various embodiments of the present disclosure. FIG. 8B is a cross-sectional view taken along line L3 of FIG. 8A. The nozzle 600b may be similar to the nozzle 600 of FIGS. 6A-6C. As such, only the differences there between will be discussed in detail.

Referring to FIGS. 8A and 8B, the nozzle 600b may include a conical nozzle tip 630a disposed on the nozzle body 620. The support structure 644 may be disposed in the opposing distal end 634 of the nozzle tip 630a. The support structure 644 may include a first support element 644a and an intersecting second support element 644b. In other words, the support structure 644 may have a horizonal cross sectional “X-shape” or cross-shape. Each of the first support element 644a and second support element 644b may extend into the nozzle chamber 636 from opposing sides of the opposing distal end 634 to form a first nozzle chamber opening 636a, second nozzle chamber opening 636b, third nozzle chamber opening 636c, and fourth nozzle chamber opening 636d.

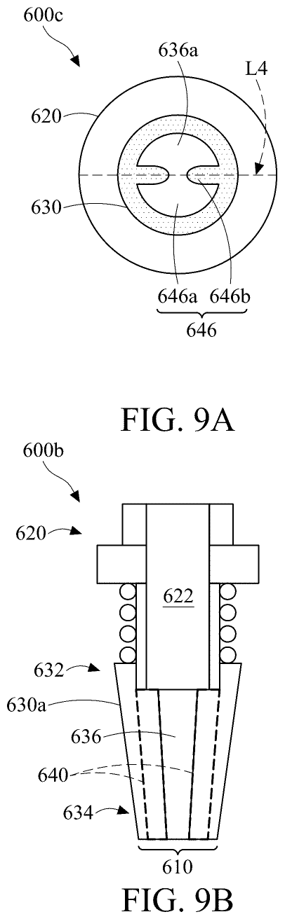

FIG. 9A is a plan view of a nozzle 600c including an alternative support structure 646, according to various embodiments of the present disclosure. FIG. 9B is a cross-sectional view taken along line L4 of FIG. 9A. The nozzle 600c may be similar to the nozzle 600b of FIGS. 8A and 8B. As such, only the differences there between will be discussed in detail.

Referring to FIGS. 9A and 9B, nozzle 600c may include a conical nozzle tip 630a disposed on the nozzle body 620. The support structure 646 may be disposed in the opposing distal end 634 of the nozzle tip 630a. The support structure 646 may include a first support element 646a and an opposing second support element 646b.

The first support element 646a and the opposing second support element 646b may extend into the nozzle chamber 636 from opposing sides of the opposing distal end 634 to form a partially divided nozzle chamber opening 636a. Terminating ends of the first support element 646a and an opposing second support element 646b may be rounded or tapered. However, in other embodiments the terminating ends of the first support element 646a and an opposing second support element 646b may be flat. In some embodiments, the terminating ends of the first support element 646a and an opposing second support element 646b may have different shapes. As shown in FIG. 9B, the first support element 646a and an opposing second support element 646b may extend in a vertical direction from the opposing distal end 634 of the nozzle tip 630a to an end of the nozzle body 620.

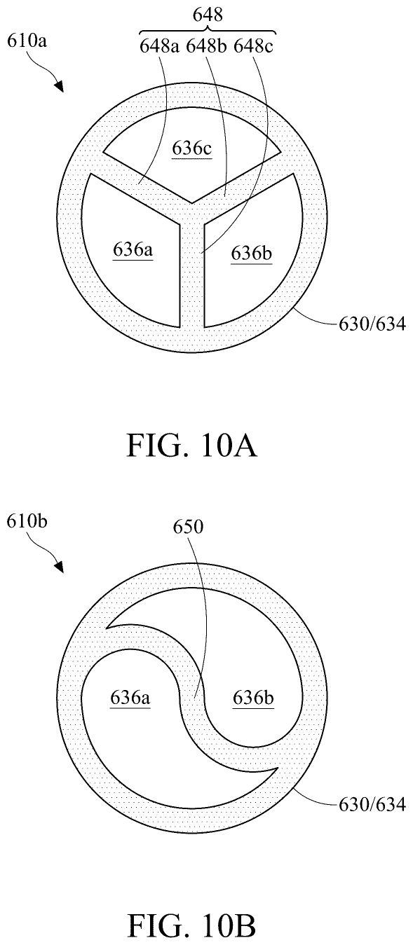

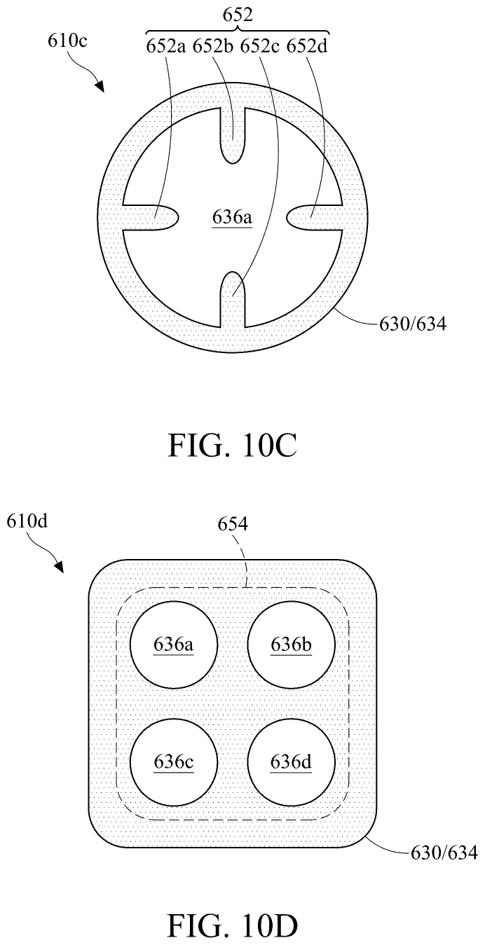

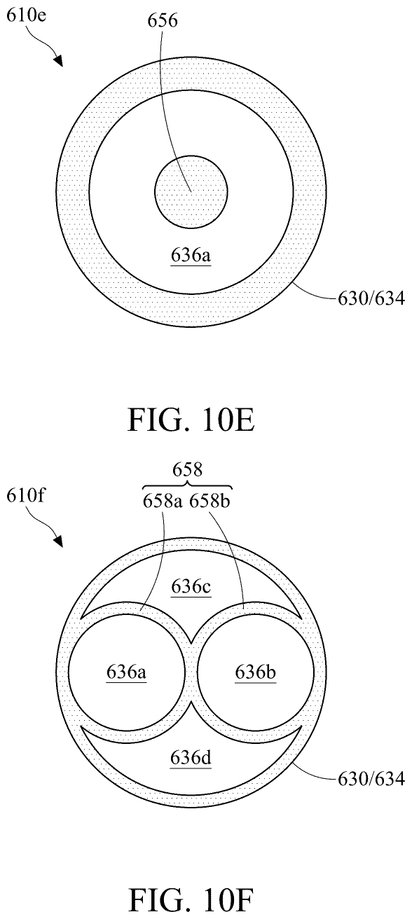

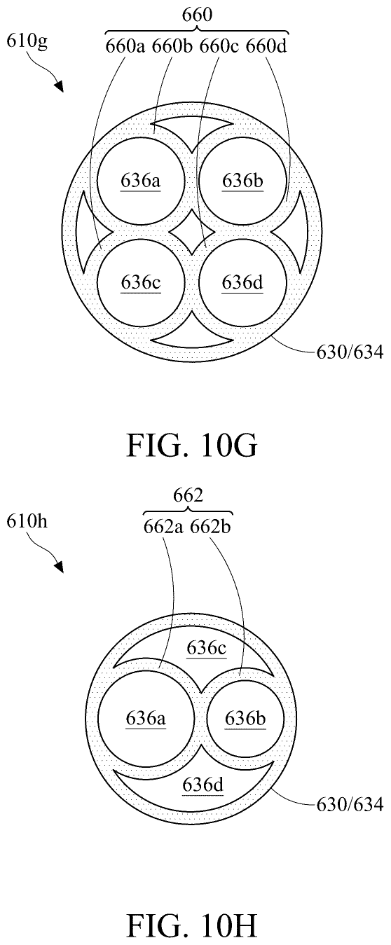

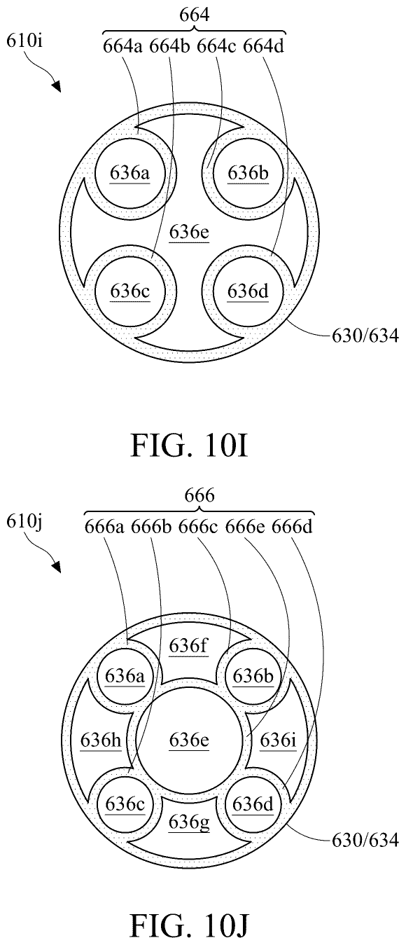

FIGS. 10A-10J are plan views illustrating the horizontal cross sectional views of contact surfaces 610a-610j formed by alternative support structures, according to various embodiments of the present disclosure. The contact surfaces 610a-610j may be utilized in any of the nozzles described herein.

Referring to FIG. 10A, the contact surface 610a may be formed by an opposing distal end 634 of a nozzle tip 630 and a support structure 648 disposed therein. The support structure 648 may include three support elements 648a, 648b, 648c that intersect at the center of the nozzle chamber 636. The support elements 648a, 648b, 648c may extend from corresponding portions of the opposing distal end 634 and may intersect in the center of the opposing distal end 634. In other words, the support structure 648 may be “Y” shaped and may extend into the nozzle chamber 636 from three sides of the opposing distal end 634 to form three nozzle chamber openings 636a, 636b, 636c. In some embodiments, the three support elements 648a, 648b, 648c may have different widths such that some, but not all of the three support elements 648a, 648b, 648c intersect at the center of the nozzle chamber 636.

Referring to FIG. 10B, the contact surface 610b may be formed by the opposing distal end 634 of a nozzle tip 630 and a support structure 650 disposed therein. The support structure 650 may extend from opposing sides of the nozzle tip 630 and may have a curved or sinusoidal shape. The support structure 650 may extend into the nozzle chamber 636 from opposing sides of the opposing distal end 634 to form two nozzle chamber openings 636a, 636b.

Referring to FIG. 10C, the contact surface 610c is formed by the opposing distal end 634 of a nozzle tip 630 and a support structure 652 disposed therein. The support structure 652 may include four support elements 652a, 652b, 652c, 652d that extend from the nozzle tip 630 towards the center of the nozzle chamber 636. The support elements 652a, 652b, 652c, 652d may have curved, flat, or tapered terminating ends in various embodiments. In an embodiment, the width of each of the four support elements 652a, 652b, 652c, 652d may be equal. In other embodiments, the width of each of the four support elements 652a, 652b, 652c, 652d may vary. In still other embodiments, the width of pairs of the four support elements the width of each of the four support elements 652a, 652b, 652c, 652d may be equal but differ from the width of the other pair of the four support elements 652a, 652b, 652c, 652d. For example, the width of support elements 652a and 652d may be equal and the width of support elements 652b and 652c may be equal, but the width of support elements 652a, 652d may be different from the width of support elements 652b and 652c. In still other embodiments, the width of some of the support elements 652a, 652b, 652c, 652d may be the same, but the width of others of the support elements 652a, 652b, 652c, 652d may be different.

Referring to FIG. 10D, the contact surface 610d may be formed by the opposing distal end 634 of a nozzle tip 630 and a support structure 654 disposed therein. The nozzle tip 630 may have a rectangular cross-section. The support structure 654 may extend into the nozzle chamber 636 at the opposing distal end 634 to form four nozzle chamber openings 636a, 636b, 636c, 636d. In some embodiments, as shown in FIG. 10D the four nozzle chamber openings 636a, 636b, 636c, 636d may have a horizontal cross-sectional shape. In other embodiments, the nozzle chamber openings 636a, 636b, 636c, 636d may have a square, rectangular, triangular, or other horizontal cross sectional shape.

Referring to FIG. 10E, the contact surface 610e may be formed by the opposing distal end 634 of a nozzle tip 630 and a support structure 656 disposed therein. The support structure 656 may be disposed in the center of the nozzle chamber 636. The support structure 656 may have a circular horizontal cross-section as shown in FIG. 10E. In other embodiments, the support structure 656 may have a square, rectangular, triangular, oval, or other horizontal cross-section. In other embodiments, multiple circular support structures may be concentric about the center of the nozzle tip 630.

Referring to FIG. 10F, the contact surface 610f may be formed by the opposing distal end 634 of a nozzle tip 630 and a support structure 658 disposed therein. The support structure 658 may include two circular support elements 658a, 658b that are directly connected to each other and to opposing sides of the opposing distal end 634. The support elements 658a, 658b may have the same or substantially the same diameter. The support structure 658 may extend into the nozzle chamber 636 at the distal end 634 to form four nozzle chamber openings 636a, 636b, 636c, 636d.

Referring to FIG. 10G, the contact surface 610g may be formed by the opposing distal end 634 of a nozzle tip 630 and a support structure 660 disposed therein. The support structure 660 may include four support elements 660a, 660b, 660c, 660d that are connected to each other and to the nozzle tip 630. The support elements 660a, 660b, 660c, 660d may have the same or substantially the same diameter. The support structure 660 may divide the distal end of a nozzle chamber to form four nozzle chamber openings 636a, 636b, 636c, 636d. In other embodiments, the four support elements 660a, 660b, 660c, 660d may have a circular, square, rectangular, triangular, oval, or other horizontal cross-section. In some embodiments, the four support elements 660a, 660b, 660c, 660d may have different horizontal cross sections from one another.

Referring to FIG. 10H, the contact surface 610h may be formed by the opposing distal end 634 of a nozzle tip 630 and a support structure 662 disposed therein. The support structure 662 may include two circular support elements 662a, 662b that are connected to each other and to the nozzle tip 630. The support elements 662a, 662b may have different diameters. The support structure 662 may divide the distal end of a nozzle chamber to form four nozzle chamber openings 636a, 636b, 636c, 636d. In other embodiments, the support structure elements 662a, 662b may have a square, rectangular, triangular, oval, or other horizontal cross-section. In some embodiments, the support structure elements 662a, 662b may have different horizontal cross sections.

Referring to FIG. 10I, the contact surface 610i may be formed by the opposing distal end 634 of a nozzle tip 630 and a support structure 664 disposed therein. The support structure 664 may include four support elements 664a, 664b, 664c, 664d that are connected to the nozzle tip 630 and are not directly connected to one another. The support elements 664a, 664b, 664c, 664d may have the same or substantially the same width/diameter. The support structure 664 may divide the distal end of a nozzle chamber to form five nozzle chamber openings 636a, 636b, 636c, 636d, 636d. In various embodiments, the four support elements 664a, 664b, 664c, 664d may have a circular, square, rectangular, triangular, oval, or other horizontal cross-section. In some embodiments, the four support elements 664a, 664b, 664c, 664d may have different horizontal cross sections from one another.

Referring to FIG. 10J, the contact surface 610j may be formed by the planar surface of the opposing distal end 634 of a nozzle tip 630 and the planar surface of a support structure 666 disposed therein. The support structure 666 may include five support elements 666a, 666b, 666c, 666d, 666e that are connected to the nozzle tip 630 to one another. The support elements 666a, 666b, 666c, 666d may have the same or substantially the same width/diameter. The support element 666e may have a larger width diameter and may be disposed inside of the support elements 666a, 666b, 666c, 666d. The support structure 666 may divide the distal end of a nozzle chamber to form nozzle chamber openings 636a, 636b, 636c, 636d, 636d, 636e, 636f, 636g, 636h, 636i. In various embodiments, the five support elements 666a, 666b, 666c, 666d, 666e may have a circular, square, rectangular, triangular, oval, or other horizontal cross-section. In some embodiments, the five support elements 666a, 666b, 666c, 666d, 666e may have different horizontal cross sections from one another.

According to various embodiments, provided is a nozzle 600 for a pick-and-place machine 10, the nozzle 600 may include: a planar contact surface 610 configured to form a fluid-tight seal with an electronic component (e.g., semiconductor die 410); a nozzle body 620 including a suction chamber 622; a nozzle tip 630 including a proximal end 632 that is attached to the nozzle body 620, an opposing distal end 634 that forms a portion of the contact surface 610, and a nozzle chamber 636 that extends from the opposing distal end 634 to the suction chamber 622; and a support structure 640 that extends into the nozzle chamber 636 from the opposing distal end 634, the support structure 640 forming a portion of the contact surface 610.

In various embodiments, the opposing distal end 634 forms a perimeter portion of the contact surface 610; and the support structure 640 forms an internal portion of the contact surface 610. In various embodiments, the support structure 640 extends into the nozzle chamber 636 from two opposing sides of the opposing distal end 634 to form two nozzle chamber openings 636a, 636b. In various embodiments, the support structure 648 extends into the nozzle chamber 636 from three sides of the opposing distal end 634 to form three nozzle chamber openings 636a, 636b, 636c. In some embodiments, support structure 644 extends into the nozzle chamber 636 from four opposing sides of the opposing distal end 634 to form four nozzle chamber openings 636a, 636b, 636c, 636d. In some embodiments, the support structure 646 includes two support elements 646a, 646b that extend into the nozzle chamber 636 from two opposing sides of the opposing distal end 634 to form a partially divided nozzle chamber opening 636a. In various embodiments, the support structure 652 includes four support elements 652a, 652b, 652c, 652d that extend into the nozzle chamber 636 from four opposing sides of the opposing distal end 634 to form a partially divided nozzle chamber opening 636a. In various embodiments, the support structure 654 forms four nozzle chamber openings 636a, 636b, 636c, 636d. In some embodiments, the support structure 658 includes at least two support elements 658a, 658b that have circular horizontal cross-sections.

In various embodiments, a nozzle for a pick-and-place machine includes: a nozzle body 620 comprising a suction chamber 622; a nozzle tip 630 comprising a proximal end 632 that is attached to the nozzle body 620, an opposing distal end 634, and a nozzle chamber 636 that extends from the opposing distal end 634 to the suction chamber 622; a support structure 640 that extends into the nozzle chamber 636 to form least two nozzle chamber openings 636a, 636b.

In various embodiments, the opposing distal end 634 and the support structure 640 form a planar contact surface 610 configured to form a fluid-tight seal with an electronic component disposed in contact with the contact surface 610. In various embodiments, nozzle 600 includes a spring 616 biased between the nozzle tip 630 and the nozzle body 620. In some embodiments, the support structure 640 is configured to reduce an amount of bending stress that is applied to the electronic component that is attached to the nozzle tip 630 by a partial vacuum generated in the suction chamber 622 and the nozzle chamber 636.

In various embodiments, provided is a pick-and-place head 100 that includes: a spindle 300; and a nozzle 600 fluidly connected to an end of the spindle 300. The nozzle 600 includes: a planar contact surface 610 configured to form a fluid-tight seal with a component; a nozzle body comprising a suction chamber 622; a nozzle tip comprising a proximal end 632 that is attached to the nozzle body 620, a distal end 634 that forms a portion of the contact surface 610, and a nozzle chamber 636 that extends from the distal end 634 to the suction chamber 622; a support structure 640 disposed in the nozzle chamber 636 and forming a portion of the contact surface 610.

In various embodiments, the support structure 640 is configured to reduce an amount of bending stress that is applied to the electronic component that is attached to the nozzle tip 630 by a partial vacuum generated in the suction chamber 622 and the nozzle chamber 636 by the pick-and-place head 100. The support structure 640 may at least partially divides an opening 636a-636e of the nozzle chamber 636 that extends through the contact surface 610.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A nozzle for a pick-and-place machine, the nozzle comprising:
a planar contact surface configured to form a fluid-tight seal with an electronic component;
a nozzle body comprising a suction chamber;
a nozzle tip comprising a proximal end that is attached to the nozzle body, an opposing distal end that forms a portion of the contact surface, and a nozzle chamber that extends from the opposing distal end to the suction chamber; and
a support structure that extends into the nozzle chamber from the opposing distal end, the support structure forming a portion of the contact surface.

2. The nozzle of claim 1, wherein:
the opposing distal end forms a perimeter portion of the contact surface; and
the support structure forms an internal portion of the contact surface.

3. The nozzle of claim 1, wherein the support structure extends into the nozzle chamber from two opposing sides of the opposing distal end to form two nozzle chamber openings.

4. The nozzle of claim 1, wherein the support structure extends into the nozzle chamber from three sides of the opposing distal end to form three nozzle chamber openings.

5. The nozzle of claim 1, wherein the support structure extends into the nozzle chamber from four opposing sides of the opposing distal end to form four nozzle chamber openings.

6. The nozzle of claim 1, wherein the support structure comprises two support elements that extend into the nozzle chamber from two opposing sides of the opposing distal end to form a partially divided nozzle chamber opening.

7. The nozzle of claim 1, wherein the support structure comprises four support elements that extend into the nozzle chamber from four opposing sides of the opposing distal end to form a partially divided nozzle chamber opening.

8. The nozzle of claim 1, wherein the support structure forms four nozzle chamber openings.

9. The nozzle of claim 1, wherein the support structure comprises at least two support elements that have circular horizontal cross-sections.

10. The nozzle of claim 9, wherein the at least two support elements are directly connected to one another.

11. The nozzle of claim 9, wherein the at least two support elements have different diameters.

12. A nozzle for a pick-and-place machine, the nozzle comprising:
a nozzle body comprising a suction chamber;
a nozzle tip comprising a proximal end that is attached to the nozzle body, an opposing distal end, and a nozzle chamber that extends from the opposing distal end to the suction chamber; and
a support structure that extends into the nozzle chamber to form at least two nozzle chamber openings.

13. The nozzle of claim 12, wherein the opposing distal end and the support structure form a planar contact surface configured to form a fluid-tight seal with an electronic component disposed in contact with the contact surface.

14. The nozzle of claim 13, wherein the at least two nozzle chamber openings extend through the contact surface.

15. The nozzle of claim 12, wherein the support structure extends into the nozzle chamber to form at least three nozzle chamber openings.

16. The nozzle of claim 13, wherein the support structure is configured to reduce an amount of bending stress that is applied to the electronic component that is attached to the nozzle tip by a partial vacuum generated in the suction chamber and the nozzle chamber.

17. The nozzle of claim 12, further comprising a spring biased between the nozzle tip and the nozzle body.

18. A pick-and-place head comprising:
a spindle; and
a nozzle that is fluidly connected to an end of the spindle, the nozzle comprising:
a planar contact surface configured to form a fluid-tight seal with an electronic component;
a nozzle body comprising a suction chamber;
a nozzle tip comprising a proximal end that is attached to the nozzle body, a distal end that forms a portion of the contact surface, and a nozzle chamber that extends from the distal end to the suction chamber; and
a support structure disposed in the nozzle chamber and forming a portion of the contact surface.

19. The pick-and-place head of claim 18, wherein the support structure is configured to reduce an amount of bending stress that is applied to the electronic component that is attached to the nozzle tip by a partial vacuum generated in the suction chamber and the nozzle chamber by the pick-and-place head.

20. The pick-and-place head of claim 18, wherein the support structure at least partially divides an opening of the nozzle chamber that extends through the contact surface.
